(19) United States
(12) Patent Application Publication
(10) Pub. No.: US 2019/0215111 A1
(43) Pub. Date: Jul. 11, 2019

(54) RECEIVER AND ASSOCIATED SIGNAL PROCESSING METHOD

(71) Applicant: MStar Semiconductor, Inc., Hsinchu Hsien (TW)

(72) Inventors: Fong Shih Wei, Hsinchu County (TW); Tai-Lai Tung, Hsinchu County (TW)

(21) Appl. No.: 16/132,527

(22) Filed: Sep. 17, 2018

(30) Foreign Application Priority Data
Jan. 10, 2018 (TW) 107100891

(51) Int. Cl. H04L 5/00; H03G 3/20; H04B 1/16; H03D 7/14; H04L 27/26

(52) U.S. Cl. CPC H04L 5/0007; H03G 3/20; H03D 2200/0025; H03D 7/14; H04L 27/2649; H04B 1/16

(57) ABSTRACT

A receiver includes a gain adjusting circuit and a timing control circuit. The gain adjusting circuit adjusts the strength of an input signal according to a gain value to generate an adjusted input signal. The timing control circuit generates a control signal according to the input signal or the adjusted input signal to determine a time point at which the gain adjusting circuit changes the gain value.

This application claims the benefit of Taiwan application Serial No. 107100891, filed Jan. 10, 2018, the subject matter of which is incorporated herein by reference.

### BACKGROUND OF THE INVENTION

### Field of the Invention

The present invention relates to a receiver, and more particularly to gain control and a signal processing method applied in a receiver.

### Description of the Related Art

In a common orthogonal frequency-division multiplexing (OFDM) receiver, a gain adjusting circuit is usually provided to adjust the strength of an input signal to an appropriate level to further facilitate the processing of a subsequent circuit. However, if a time point at which the gain adjusting circuit switches the gain value coincides with a transmission period of a symbol, inter-carrier interference (ICI) is generated, which leads to issues in subsequent signal processing.

### SUMMARY OF THE INVENTION

Therefore, it is an object of the present invention to provide a receiver capable of controlling a gain adjusting circuit to change/switch a gain at a specific time point, so as to prevent inter-carrier interference (ISI) and hence solving the issue of the prior art.

A receiver is disclosed according to an embodiment of the present invention. The receiver includes a gain adjusting circuit and a timing control circuit. The gain adjusting circuit adjusts the strength of an input signal according to a gain value to generate an adjusted input signal. The timing control circuit generates a control signal according to the input signal or the adjusted input signal to determine a time point at which the gain adjusting circuit changes the gain value.

A signal processing method is disclosed according to another embodiment of the present invention. The method includes: adjusting the strength of an input signal according to a gain value; and generating a control signal according to the input signal or the adjusted input signal to determine a time point at which the gain value is changed.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 is a block diagram of a receiver according to an embodiment of the present invention;

FIG. 2 is a schematic diagram of an input signal or an adjusted input signal according to an embodiment of the present invention;

FIG. 3 is a schematic diagram of a timing control circuit generating a control signal;

FIG. 4 is a schematic diagram of a gain adjusting circuit according to an embodiment of the present invention; and

FIG. 5 is a flowchart of a signal processing method according to an embodiment of the present invention.

### DETAILED DESCRIPTION OF THE INVENTION

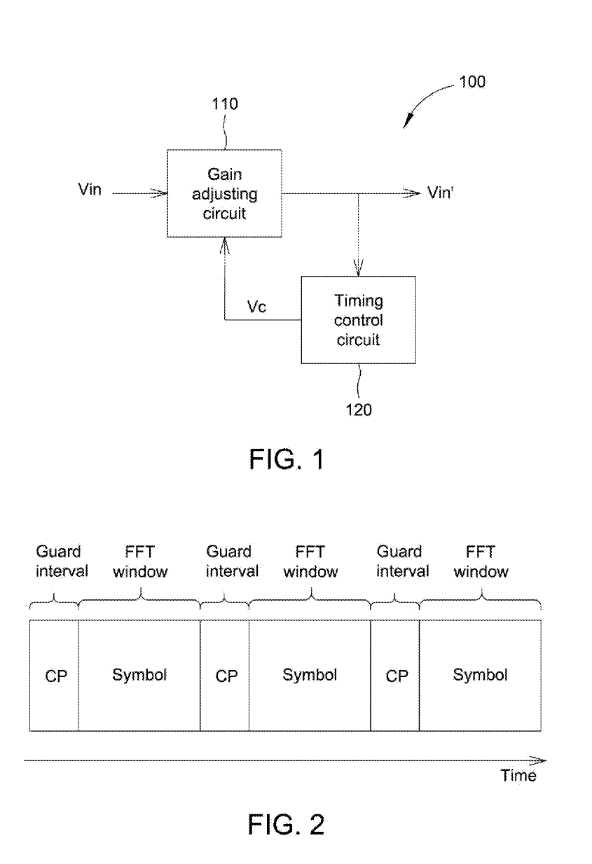

FIG. 1 shows a block diagram of a receiver 100 according to an embodiment of the present invention. As shown in FIG. 1, the receiver 100 includes a gain adjusting circuit 110 and a timing control circuit 120. In the operation of the receiver 100, the gain adjusting circuit 110 receives an input signal Vin, and uses a gain value to adjust the strength of the input signal Vin to generate an adjusted input signal Vin′ for a subsequent circuit to use. Further, the timing control circuit 120 generates a control signal Vc to the gain adjusting circuit 110 according to the adjusted input signal Vin′, so as to determine a time point at which the gain adjusting circuit 110 changes/switches the gain value. For example, the control signal Vc may be used to represent a specific time point, and changing the gain value by the gain adjusting circuit 110 at the specific time point does not cause inter-carrier interference (ICI).

In this embodiment, the receiver 100 is an orthogonal frequency-division multiplexing (OFDM) receiver, and conforms to any one of the standards including Digital Video Broadcasting-Terrestrial (DVB-T), Digital Video Broadcasting-Second Generation Terrestrial (DVB-T2), Digital Terrestrial Multimedia Broadcasting (DTMB) and Integrated Service Digital Broadcasting (ISDB). FIG. 2 shows a schematic diagram of an input signal Vin or an adjusted input signal Vin′ according to an embodiment of the present invention. As shown in FIG. 2, the input signal Vin or the adjusted input signal Vin′ is an OFDM signal, and includes multiple symbols. Between every two symbol is a cyclic prefix (CP), each symbol may correspond to a fast Fourier transform (FFT) window, and each cyclic prefix may be regarded as a guard interval. The structure of the input signal Vin or the adjusted input signal Vin′ is generally known to a person skilled in the art, and associated details are omitted herein.

In this embodiment, the timing control circuit 120 determines a time point of the cyclic prefix (the guard interval) by detecting the adjusted input signal Vin′, and accordingly generates a control signal Vc to the gain adjusting circuit 110. According to the control signal Vc, the gain adjusting circuit 110 changes the gain value only during the period of the cyclic prefix (the guard interval) shown in FIG. 2 to change the strength adjustment level of the input signal Vin, and does not change the gain value during the transmission period of the symbols shown in FIG. 2.

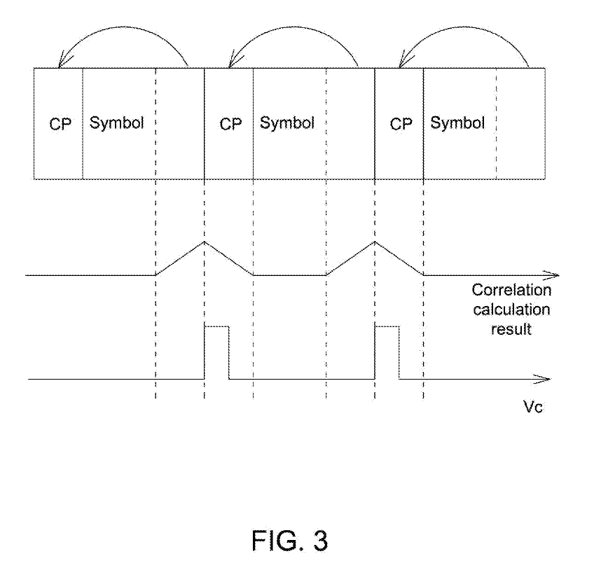

In one embodiment, the timing control circuit 120 performs a correlation calculation on the adjusted input signal Vin′ to determine the time point of the cyclic prefix (the guard interval), and accordingly determines the control signal Vc. More specifically, referring to FIG. 3, because the content of the cyclic prefix is identical to the content of the last section of the following symbol, the timing control circuit 120 may perform a correlation calculation (e.g., respectively performing multiplication and then addition on the data) on data in a time interval and data in a time interval after a time period to generate correlation calculation result, wherein the time period is a time difference between a cyclic prefix and the last section of the following symbol. As shown in FIG. 3, by sequentially moving the time interval to perform the correlation calculation, the correlation calculation results show a peak value on the time axis, wherein the peak value reflects the starting time point of the cyclic prefix (the guard interval). Next, the timing control circuit 120 can generate, at the starting point of the cyclic prefix (the guard interval), the control signal Vc having a pulse to notify the gain adjusting circuit 110 that the current time point is the starting time point of the cyclic prefix of the adjusted input signal Vin′, and the gain adjusting circuit 110 can accordingly change the gain value. In other embodiments, the control signal Vc is not necessarily generated at the starting time point of the cyclic prefix (the guard interval), and any control signal Vc capable of controlling the gain adjusting circuit 110 to accordingly change the gain value within the interval of the cyclic prefix is encompassed within the scope of the present invention. Further, although the timing control circuit 120 determines the time point of the cyclic prefix (the guard interval) according to the adjusted input signal Vin′ in this embodiment, the timing control circuit 120 may also directly determine the time point of the cyclic prefix (the guard interval) according to the input signal Vin in other embodiments. Regardless of whether the input signal Vin or the adjust input signal Vin′ is used as the basis, any signal that can be accordingly calculated by the timing control circuit 120 to determine the cyclic prefix (the guard interval) is encompassed within the scope of the present invention.

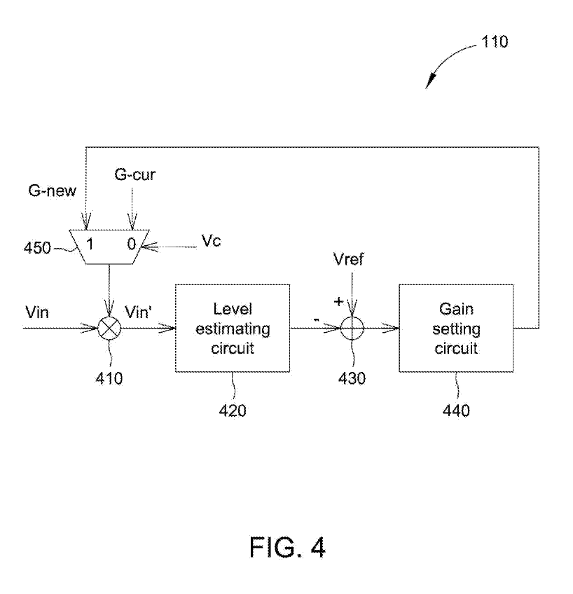

FIG. 4 shows a schematic diagram of the gain adjusting circuit 110 according to an embodiment of the present invention. As shown in FIG. 4, the gain adjusting circuit 110 includes a multiplier 410, a level estimating circuit 420, an error calculating circuit 430, a gain setting circuit 440, and a multiplexer 450. In the operation of the gain adjusting circuit 110, the multiplier 410 multiplies the input signal Vin by a gain value from the multiplexer 450 to generate the adjusted input signal Vin′. The level estimating circuit 420 estimates a level of the adjusted input signal Vin′. For example, the level estimating circuit 420 may calculate a moving average strength value or a peak value of the adjusted input signal Vin′ as the level. The error calculating circuit 430 calculates a difference between the level of the adjusted input signal Vin′ and a reference level Vref, wherein the reference level Vref may be regarded as an ideal value or a target value of the level of the adjusted input signal Vin′. The gain setting circuit 440 then generates a new gain value G-new according to the difference. The multiplexer 450 selectively transmits the gain value G-new or a gain value G-cur to the multiplier 410 according to the control signal Vc generated by the timing control circuit 120, wherein the gain value G-cur is the gain value currently used by the multiplier 410. More specifically, referring to FIG. 3 and FIG. 4, when the adjusted input signal Vin′ is in the transmission period of a symbol, because the control signal Vc is at a low-voltage level (corresponding to logic “0”), the multiplexer 450 outputs the currently used gain value G-cur to be used for strength adjustment to the multiplier 410, i.e., the gain value used by the multiplexer 450 does not change (kept at the gain value G-cur). When the adjusted input signal Vin′ enters the transmission period of a cyclic prefix, because the control signal Vc is at a high-voltage level (corresponding to logic “1”), the multiplexer 450 outputs the new gain value G-new to be used for strength adjustment to the multiplier 410.

Although the gain value provided to the multiplier 410 is changed through the multiplexer 450 according to the control signal Vc, the present invention is not limited thereto. Any design that changes the gain value used by the multiplier 410 during the transmission period of a cyclic prefix according to the control signal Vc is encompassed within the scope of the present invention.

In this embodiment, the gain adjusting circuit 110 and the timing control circuit 120 are provided in a demodulator; in another embodiment of the present invention, the gain adjusting circuit 110 may be provided in a tuner, and the timing control circuit 120 may be provided in a demodulator.

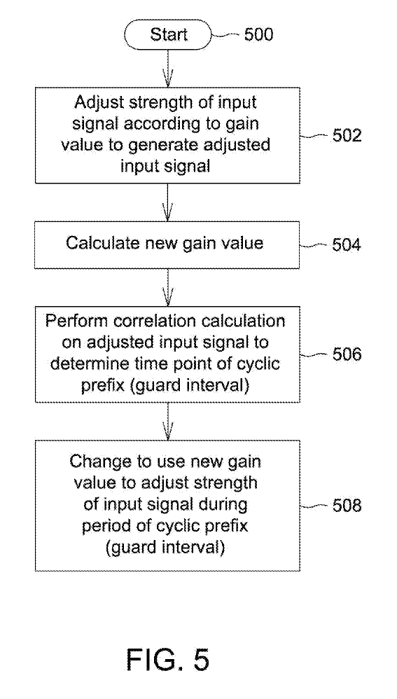

FIG. 5 shows a flowchart of a signal processing method according to an embodiment of the present invention. Referring to the disclosure of the above embodiments, the process is as follows.

In step 500, the process begins.

In step 502, the strength of an input signal is adjusted according to a gain value to generate an adjusted input signal.

In step 504, a new gain value is calculated. In this embodiment, a difference is calculated according to a level of the adjusted input signal and a reference level Vref, and the new gain value is calculated according to the difference.

In step 506, a correlation calculation is performed on the adjusted input signal to determine a time point of a cyclic prefix (a guard interval).

In step 508, the new gain value is switched to and used during the period of the cyclic prefix (the guard interval) to adjust the strength of the input signal.

In conclusion of the present invention, in the receiver and the signal processing method of the present invention, the gain value is changed during the guard interval of an input signal or an adjusted input signal, and the gain value used in the transmission period of a symbol is kept unchanged, thus preventing the ICI occurring in the prior art and facilitating subsequent signal processing.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A receiver, comprising:
a gain adjusting circuit, adjusting a strength of an input signal according to a gain value to generate an adjusted input signal; and
a timing control circuit, generating a control signal according to the input signal or the adjusted input signal to determine a time point at which the gain adjusting circuit changes the gain value.

2. The receiver according to claim 1, wherein the gain adjusting circuit changes the gain value only at the time point.

3. The receiver according to claim 1, wherein the input signal and the adjust input signal comprise a plurality of symbols, a guard interval is between every two consecutive symbols, and the time point is within a period of the guard interval.

4. The receiver according to claim 3, wherein data content included in the guard interval is identical to a part of data content of a plurality of adjacent consecutive symbols, and the timing control circuit performs a correlation calculation on the data content included in the guard interval and the part of data content to calculate a position of the guard interval and accordingly generates the control signal.

5. The receiver according to claim 1, wherein the timing control circuit performs the correlation calculation on the input signal or the adjusted input signal to generate the control signal.

6. The receiver according to claim 1, wherein the gain adjusting circuit comprises:
a multiplier, multiplying the input signal by the gain value to generate the adjusted input signal;
a level estimating circuit, coupled to the multiplier, estimating a level of the adjusted input signal;
an error calculating circuit, coupled to the level estimating circuit, calculating a difference between the level of the adjusted input signal and a reference level; and
a gain setting circuit, coupled to the error calculating circuit, generating the gain value according to the difference;
wherein, the multiplier changes the gain value according to the control signal.

7. The receiver according to claim 6, wherein the gain adjusting circuit further comprises:
a multiplexer, changing from providing the gain value to the multiplier to providing the changed gain value to the multiplier according to the control signal at the time point.

8. The receiver according to claim 1, wherein the gain adjusting circuit and the timing control circuit are provided in a demodulator.

9. The receiver according to claim 1, wherein the gain adjusting circuit is provided in a tuner, and the timing control circuit is provided in a demodulator.

10. A signal processing method, applied to a receiver, comprising:
adjusting a strength of an input signal according to a gain value to generate an adjusted input signal; and
generating a control signal according to the input signal or the adjusted input signal to determine a time point at which the gain value is changed.

11. The signal processing method according to claim 10, further comprising:
changing the gain value only at the time point.

12. The signal processing method according to claim 10, wherein the input signal and the adjusted input signal comprise a plurality of symbols, a guard interval is between every two consecutive symbols, and the time point is within a period of the guard interval.

13. The signal processing method according to claim 12, wherein data content included in the guard interval is identical to a part of data content of a plurality of consecutive symbols, and the step of generating the control signal according to the input signal or the adjusted input signal comprises:
performing a correlation calculation on the data content included in the guard interval and the part of data content to calculate a position of the guard interval, and accordingly generating the control signal.

14. The signal processing method according to claim 10, wherein the step of generating the control signal according to the input signal or the adjusted input signal comprises:
performing a correlation calculation on the input signal or the adjusted input signal to generate the control signal.

15. The signal processing method according to claim 10, wherein the adjusted input signal is generated by a multiplier multiplying the gain value with the input signal, the signal processing method further comprising:
estimating a level of the adjusted input signal;
calculating a difference between the level of the adjusted input signal and a reference level; and
generating the gain value according to the difference;
wherein, the multiplier changes the gain value according to the control signal.

16. The signal processing method according to claim 15, further comprising:
using a multiplexer to change from providing the gain value to the multiplier to providing the changed gain value to the multiplier according to the control signal at the time point.

17. The signal processing method according to claim 10, applied in a demodulator.

18. The signal processing method according to claim 10, wherein the step of generating the adjusted input signal is performed by a tuner, and the step of generating the control signal is performed by a demodulator.
